(19) United States
(12) Patent Application Publication
(10) Pub. No.: US 2022/0045305 A1
(43) Pub. Date: Feb. 10, 2022

(54) Flexible Cover Window and Flexible Device Including the Same

(71) Applicants: SK Innovation Co., Ltd., Seoul (KR); SK ie technology Co., Ltd., Seoul (KR)

(72) Inventors: Hyun Joo Song, Daejeon (KR); Hye Jin Kim, Daejeon (KR); Min Sang Park, Daejeon (KR); Keon Hyeok Ko, Daejeon (KR)

(21) Appl. No.: 17/392,333

(22) Filed: Aug. 3, 2021

(30) Foreign Application Priority Data
Aug. 4, 2020 (KR) 10-2020-0097288

(51) Int. Cl. H01L 51/52; G02B 5/30; H01L 51/00; C08G 73/14

(52) U.S. Cl. CPC H01L 51/5281; G02B 5/305; G02B 5/3083; H01L 2251/558; H01L 51/0035; C08G 73/14; H01L 2251/5338; H01L 51/0097

(57) ABSTRACT

Provided are a flexible cover window and a flexible device including the same. More particularly, a flexible cover window which has excellent visibility and is flexible and a flexible device including the same are provided.

### CROSS-REFERENCE TO RELATED APPLICATION

This application claims priority to Korean Patent Application No. 10-2020-0097288 filed Aug. 4, 2020, the disclosure of which is hereby incorporated by reference in its entirety.

### BACKGROUND OF THE INVENTION

### Field of the Invention

The following disclosure relates to a flexible cover window and a flexible device including the same. More particularly, the following disclosure relates to a flexible cover window which has excellent visibility and is flexible and a flexible device including the same.

### Description of Related Art

An organic light emitting diode (hereinafter, referred to as “OLED”) is a display device which may show information such as images and texts using light produced by combining holes and electrons which are provided from an anode and a cathode, respectively, in an organic light emitting layer positioned between the anode and the cathode. Since the organic light emitting diode has various advantages such as a wide viewing angle, a rapid response speed, a small thickness, and a low power consumption, it is spotlighted as a promising next-generation display device.

Though OLED is self-luminous and may have no polarizing plate during color implementation, a polarizing plate for OLED is used for implementing a black color and preventing external light reflection. Usually, as the polarizing plate for OLED, a polarizing plate to which a λ/4 retardation film is attached is used for solving visibility deterioration by reflected light produced when external light is reflected on an OLED backplane.

In addition, a glass substrate is used on the polarizing plate for protecting an outer surface, but the glass substrate has a limitation in imparting a lighter weight, a smaller thickness, and flexibility.

A study on flexible OLED which may be bent or warped by replacing the conventional glass substrate having no flexibility with a plastic material having flexibility as a cover window is actively conducted.

However, when a polymer film is used for replacing the conventional glass, a polymer film has optical retardation, and thus, as a polarized light which has passed through a polarizing plate passes a flexible cover window, polarization interference due to phase delay occurs. The polarization interference causes visibility deterioration such as color mixing when a device to which a display is applied is used. In addition, since sometimes the polymer film has low mechanical strength and lacks thermal resistance and transparent, as compared with glass, the physical properties of the polymer film itself needs to be improved for applying the film to flexible OLED which needs to be bent, rolled, or the like repeatedly.

### RELATED ART DOCUMENTS

### Patent Documents

(Patent Document 1) Korean Patent Registration Publication No. 10-1659121 (Sep. 13, 2016)

### SUMMARY OF THE INVENTION

An embodiment of the present invention is directed to providing a flexible OLED cover window which allows a glass substrate of OLED to be replaced with a polymer film, more specifically, a polyimide-based film, and has small polarization interference and excellent visibility, and a flexible OLED device including the same.

Another embodiment of the present invention is directed to providing a polyimide-based film having excellent mechanical physical properties, high thermal resistance, transparency, excellent visibility, and an improved rainbow or optical stain phenomenon, a flexible OLED cover window using the same, and a flexible OLED device including the same.

Still another embodiment of the present invention is directed to providing a new flexible OLED cover window which replaces glass, and thus, satisfies excellent mechanical physical properties and various optical properties and also may solve a light distortion problem, and a flexible OLED device including the same.

As a result of study for achieving the object, it was found that a flexible OLED cover window having excellent visibility and quality may be provided by placing a polyimide-based film satisfying an in-plane retardation in a specific range on an OLED polarizing plate, so that an angle between an in-plane slow axis (optic axis) of the polyimide-based film and a transmittance axis or an absorption axis of the OLED polarizing plate is 20° or less.

In one general aspect, a flexible cover window on a display includes: a polarizing plate on an organic light emitting diode and a polyimide film layer on the polarizing plate, wherein the polyimide film layer has one or two or more layers of polyimide-based films having an in-plane retardation of 300 nm or less as measured at a wavelength of 550 nm, and an angle between an in-plane slow axis (optic axis) of the polyimide-based film which is adjacent to the polarizing plate and a transmittance axis or an absorption axis of the polarizing plate is 20° or less.

In an exemplary embodiment, when two or more layers of the polyimide-based films are placed on the polarizing plate, an angle between in-plane slow axes (optic axes) of adjacent polyimide-based films may be 20° or less.

In an exemplary embodiment, the polyimide-based film may have the in-plane retardation of 100 to 300 nm, as measured at a wavelength of 550 nm.

In an exemplary embodiment, a transmittance may satisfy the following Equation 1, as measured in a state in which a second polarizing plate having a polarization degree of 99% or more is placed on the polyimide film layer to be orthogonal to the transmittance axis of the polarizing plate.

10%≤(B/A)×100≤50% [Equation 1]

wherein A is a transmittance in a state of the second polarizing plate being removed, and B is a transmittance measured after the second polarizing plate is placed on the polyimide-based film so that the transmittance axis of the second polarizing plate is orthogonal to the transmittance axis of the polarizing plate.

In an exemplary embodiment, the polyimide-based film may have a modulus in accordance with ASTM D882 of 3 GPa or more, an elongation at break of 8% or more, a light transmittance of 5% or more as measured at 388 nm in accordance with ASTM D1746, a total light transmittance of 87% or more as measured at 400 to 700 nm, a haze of 2.0% or less, a yellow index of 5.0 or less, and a b* value of 2.0 or less as measured by a colorimeter.

In an exemplary embodiment, the polyimide-based film may be formed of a polyamide-imide-based resin.

In an exemplary embodiment, the polyimide-based film may include a unit derived from a fluorine-based aromatic diamine, a unit derived from an aromatic dianhydride, and a unit derived from an aromatic diacid dichloride.

In an exemplary embodiment, the polyimide-based film may further include a unit derived from a cycloaliphatic dianhydride.

In an exemplary embodiment, the polyimide-based film may have a thickness of 30 to 110 μm.

In an exemplary embodiment, an adhesive layer may be further included on one surface or both surfaces of the polyimide-based film.

In an exemplary embodiment, a hard coating layer may be further included on one surface or both surfaces of the polyimide-based film.

In an exemplary embodiment, the polarizing plate may include a polarizer and a λ/4 retardation layer.

In another general aspect, a flexible display device includes the flexible cover window according to the exemplary embodiment.

In an exemplary embodiment, the display device may be an organic light emitting diode display device.

Other features and aspects will be apparent from the following detailed description, the drawings, and the claims.

### BRIEF DESCRIPTION OF THE DRAWINGS

FIG. 1 illustrates a multilayer structure of a flexible OLED cover window according to an exemplary embodiment of the present invention.

FIG. 2 illustrates a multilayer structure of a flexible OLED cover window according to an exemplary embodiment of the present invention.

FIG. 3 illustrates a multilayer structure for measuring a transmittance of the flexible OLED cover window according to an exemplary embodiment of the present invention.

### DETAILED DESCRIPTION OF MAIN ELEMENTS

10: light source
20: first polarizing plate
21: transmittance axis or absorption axis of first polarizing plate
30: first polyimide-based film
31: in-plane slow axis of first polyimide-based film
40: second polyimide-based film
41: in-plane slow axis of second polyimide-based film
50: second polarizing plate
51: transmittance axis or absorption axis of second polarizing plate

### DESCRIPTION OF THE INVENTION

Hereinafter, the present disclosure will be described in detail. However, the following exemplary embodiment is only a reference for describing the present invention in detail, and the present invention is not limited thereto and may be implemented in various forms.

In addition, unless otherwise defined, all technical terms and scientific terms have the same meanings as those commonly understood by a person skilled in the art to which the present invention pertains.

The terms used herein are only for effectively describing a certain specific example, and are not intended to limit the present invention.

In addition, the singular form used in the specification and claims appended thereto may be intended to also include a plural form, unless otherwise indicated in the context.

In addition, unless particularly described to the contrary, “comprising” any elements will be understood to imply further inclusion of other elements rather than the exclusion of any other elements.

In the present invention, a polyimide-based resin is used as a term including polyimide or polyamide-imide. A polyimide-based film is used as a term having a meaning encompassing a polyimide film or a polyamide-imide film.

In the present invention, a “polyimide-based resin solution” is used in the same meaning as a “composition for forming a polyimide-based film” and a “polyamide-imide solution”.

In addition, a polyimide-based resin and a solvent may be included for forming the polyimide-based film.

In the present invention, a “film” is obtained by applying the “polyimide-based resin solution” on a substrate, and performing drying and peeling off, and may be stretched or unstretched.

The inventors of the present invention conducted many studies for solving the above problems, and as a result, found that a cover window used in an OLED display, including an OLED polarizing plate and at least one layer of a polyimide-based film having an in-plane retardation of 300 nm or less as measured at a wavelength of 550 nm placed on the polarizing plate, which is a transparent film having improved appearance quality, having a low reflectance, and having excellent visibility, may be provided in a range in which an angle between an in-plane slow axis (optic axis) of the polyimide-based film which is adjacent to the OLED polarizing plate and a transmittance axis or an absorption axis of the OLED polarizing plate is 20° or less, thereby completing the present invention.

In a range in which the angle between the in-plane slow axis (optic axis) of the polyimide-based film and the transmittance axis or the absorption axis of the OLED polarizing plate is more than 20°, color mixing occurs, so that visibility is deteriorated and a color shift phenomenon may occur. In addition, an optical stain such as rainbow or mura may occur.

Specifically, the angle between the in-plane slow axis (optic axis) of the polyimide-based film and the transmittance axis or the absorption axis of the OLED polarizing plate may be 18° or less, more specifically 15° or less, and more specifically 10° or less, and most specifically, the angle between the in-plane slow axis (optic axis) of the polyimide-based film and the transmittance axis or the absorption axis of the OLED polarizing plate may be 0°.

In addition, the polyimide-based film may have an in-plane retardation of 300 nm or less, more specifically 100 to 300 nm, as measured at a wavelength of 550 nm, and in the range, visibility is improved, which is thus preferred. When the in-plane retardation is more than 300 nm, deterioration of optical properties such as rainbow mura or a decrease in color uniformity may occur.

Hereinafter, each component of the flexible OLED cover window of the present invention and the polyimide-based film used therein will be described.

<Flexible OLED Cover Window>

The flexible OLED cover window according to an exemplary embodiment of the present invention includes an OLED polarizing plate and at least one layer of a polyimide-based film placed on the polarizing plate, the polyimide-based film having an in-plane retardation of 300 nm or less as measured at a wavelength of 550 nm, wherein an angle between an in-plane slow axis (optic axis) of the polyimide-based film which is adjacent to the OLED polarizing plate and a transmittance axis or an absorption axis of the OLED polarizing plate is 20° or less.

The OLED polarizing plate may be used without limitation as long as it is commonly used in the art. Specifically, for example, the OLED polarizing plate may include a polarizer and a λ/4 retardation layer.

A thickness of the OLED polarizing plate is not limited, but may be 5 μm to 200 μm, specifically 10 to 150 μm, and the OLED polarizing plate may be appropriate for use in this range.

The OLED polarizing plate may have a polarization degree of 90% or more, specifically 90 to 99.99%. In the range, it may be used as a polarizing plate in an OLED device.

The polarizing plate may have a transmittance of 38% or more, specifically 40 to 49% at a wavelength of 550 nm. In the range, it may be used as a polarizing plate in an OLED device.

The polarizer may include a common polarizer having polarization performance. In a specific example, as the polarizer, a linear polarizer to which a function to absorb a linearly polarized light having a vibration plane in a specific direction by adsorbing and orienting a dichromatic coloring on a polyvinyl alcohol-based resin and transmit a linearly polarized light having a vibration plane in a direction orthogonal thereto is imparted, may be used. The dichromatic coloring may include iodine or a dichromatic organic dye.

Usually, the polarizer may be produced by uniaxial stretching of a polyvinyl alcohol-based resin film, dyeing with a dichromatic coloring, and treatment with boric acid after dyeing.

The polarizer may have a thickness of 4 μm to 30 μm, but is not limited thereto.

The λ/4 retardation layer may be a retardation film having a λ/4 retardation value in a plane direction and also having reverse wavelength dispersity. The “reverse wavelength dispersibility” refers to a tendency in which a front retardation value (R₀) or Nz at a wavelength of 380 nm to 780 nm to a front retardation value or Nz at a reference wavelength is increased with an increased wavelength. The reference wavelength may be 550 nm.

The λ/4 reverse wavelength dispersion retardation film may be combined with a polarizer to provide a function as an anti-reflection filter for OLED.

The retardation film may have a front retardation (R₀) of 100 nm to 200 nm, a retardation in a thickness direction (Rth_{B}) represented by the following Mathematical Formula 1 of 0 nm to 300 nm, a degree of biaxiality (Nz_{B}) represented by the following Mathematical Formula 2 of 0.8 to 1.2, and an in-plane retardation (Re_{B}) represented by the following Mathematical Formula 3 of 100 nm to 200 nm, at a wavelength of 550 nm:

Rth_{B}=((nx_{B}+ny_{B})/2−nz_{B})×d_{B} [Mathematical Formula 1]

Nz_{B}=(nx_{B}−nz_{B})/(nx_{B}−ny_{B}) [Mathematical Formula 2]

Re_{B}=(nx_{B}−ny_{B})×d_{B} [Mathematical Formula 3]

wherein nx_{B}, ny_{B}, and nz_{B} are a refractive index in an x-axis direction, a refractive index in a y-axis direction, and a refractive index in a z-axis direction, respectively, and d_{B} is a thickness of the retardation film (unit: nm).

The retardation film may be divided into an x-axis direction which is a machine direction (MD), a y-axis direction which is a transverse direction (TD), and a z-axis direction which is a thickness direction, of the retardation film.

In a specific example, assuming that a polarizing plate including the retardation film is placed on an OLED panel, when a front viewing angle is 0°, the left direction with respect to the front is “−”, and the right direction with respect to the front is “+”, the retardation film may have a phase delay difference (R₀) of 45 nm to 145 nm with respect to the transmittance axis of the retardation film, at a side viewing angle of −75° to 0° and 0° to +75° at a wavelength of 550 nm.

In addition, the retardation film may have a phase delay difference (R₀) of 145 nm to 200 nm with respect to an absorption axis of the retardation film, at a side viewing angle of −75° to 0° and 0° to +75° at a wavelength of 550 nm.

For the retardation film, the absorption axis of the polarizer and the optical axis (absorption axis) of the retardation film may be diagonally oriented to each other at 43° to 47° or 133° to 137° so that an angle between the absorption axis and the optical axis is 430 to 470 or 1330 to 137°.

The retardation film may be placed on the polarizer by an adhesive layer. In a specific example, the adhesive layer may include an adhesive layer formed of a water-based adhesive, a pressure-sensitive adhesive, a UV-based adhesive, or the like. For example, the adhesive layer may be formed of a polyvinyl alcohol-based water-based adhesive.

The retardation film may be a film made of a transparent resin. In a specific example, the retardation film may include a film including one or more of a polycarbonate (PC)-based resin, a cycloolefin polymer (COP)-based resin, an acrylic resin, and a cellulose-based resin.

The retardation film may have a thickness of 50 to 100 μm, specifically 50 to 75 μm. In the range, the retardation film may be used as the polarizing plate.

The polyimide-based film may be placed on the polarizer or the retardation film of the polarizing plate, and at least one or more layers may be placed.

More specifically, for example, one or two layers of the polyimide-based film may be placed, and the polyimide-based film may be used alone or a coating layer may be included on one surface of both surfaces of the polyimide-based film. The coating layer is for imparting functionality, and may be variously applied depending on the purpose. Specifically, for example, the coating layer may include any one or more layers selected from a hard coating layer, a restoration layer, a shock spread layer, a self-cleaning layer, an anti-fingerprint layer, an anti-scratch layer, a low-refractive layer, an shock absorption layer, and the like, but is not limited thereto. More preferably, a hard coating layer may be formed with the coating layer.

The coating layer may be used without limitation as long as it is commonly used in the art.

In addition, the polyimide-based film may be placed so that an angle between an in-plane slow axis (optic axis) of the polyimide-based film which is adjacent to the OLED polarizing plate of the polyimide-based films and a transmittance axis or an absorption axis of the OLED polarizing plate is 20° or less, and it is characterized in that an in-plane retardation measured at a wavelength of 550 nm is 300 nm or less. When both of the ranges are satisfied, a flexible OLED cover window having excellent visibility may be provided.

In addition, when two or more layers of the polyimide-based films a replaced, it is preferred that the films are placed so that an angle between the in-plane slow axes (optic axes) of each film is 20° or less. More preferably, it is placed so that an angle between the in-plane slow axes (optic axes) of the polyimide-based film which is adjacent to the polarizing plate and the polyimide-based film on the outermost surface is 20° or less.

More specifically, two sheets of the polyimide-based films may be placed on the OLED polarizing plate, and may be placed so that an angle between the in-plane slow axes (optic axes) of the two sheets of the polyimide-based films is 20° or less, thereby providing a flexible OLED cover window having better visibility.

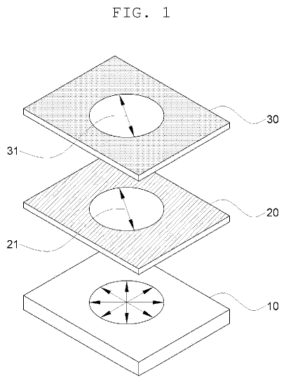

More specifically, referring to the drawings, as shown in FIG. 1, on a light source 10 such as OLED, a first polarizing plate 20 is provided and a first polyimide-based film 30 is placed on the first polarizing plate 20, in which the polyimide-based film may be placed so that an angle between the transmittance axis or the absorption axis 21 of the first polarizing plate 20 and the in-plane slow axis (optic axis) 31 of the first polyimide-based film 30 may be 20° or less.

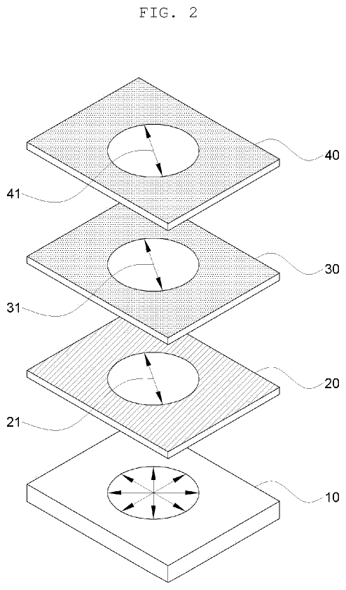

In addition, two layers or more of the polyimide-based films may be placed, and FIG. 2 illustrates a case in which two layers are placed. As shown in FIG. 2, on a light source 10 such as OLED, a first polarizing plate 20 is provided, and a first polyimide-based film 30 and a second polyimide-based film 40 may be placed on the first polarizing plate 20. Here, the polyimide-based films are placed so that the angle between the transmittance axis or the absorption axis 21 of the polarizing plate and the in-plane slow axis (optic axis) 31 of the first polyimide-based film 30 is 20° or less, and preferably, placed so that the angle between the in-plane slow axis (optic axis) of the first polyimide-based film 30 and the in-plane slow axis (optic axis) of the second polyimide-based film 40 is 20° or less, more specifically, the angle between the in-plane slow axis (optic axis) of the first polyimide-based film 30 and the in-plane slow axis (optic axis) of the second polyimide-based film 40 may be 0°.

FIGS. 1 and 2 illustrate an embodiment of the present invention for more detailed description, but the present invention is not limited thereto.

An adhesive layer may be further included on one surface or both surfaces of the polyimide-based film. More preferably, the adhesive layer may be formed of an optical adhesive layer, and the polyimide-based film and the polarizing plate may be integrated.

As the optical adhesive layer, any optical adhesive may be used without limitation as long as it is commonly used in the art. More preferably, an optical adhesive having a transmittance of 80% or more may be used.

In addition, a functional coating layer may be further included on one surface or both surfaces of the polyimide-based film. The functional coating layer is for imparting functionality, and may be variously applied depending on the purpose. Specifically, for example, the coating layer may include any one or more layers selected from a hard coating layer, a restoration layer, a shock spread layer, a self-cleaning layer, an anti-fingerprint layer, an anti-scratch layer, a low-refractive layer, an shock absorption layer, and the like, but is not limited thereto.

The coating layer may be used without limitation as long as it is commonly used in the art.

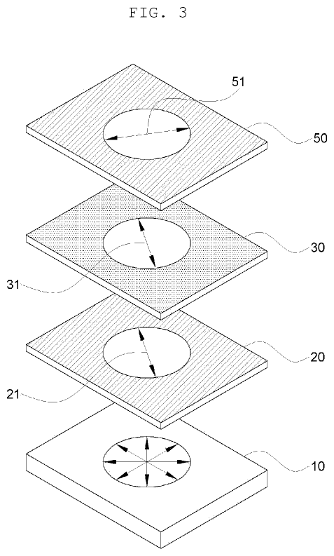

FIG. 3 illustrates a multilayer structure for measuring a transmittance of the flexible OLED cover window according to an exemplary embodiment of the present invention. As shown in FIG. 3, a second polarizing plate 50 having a polarization degree of 99% or more is placed on a first polyimide-based film 30, and herein a transmittance is measured in a state in which a transmittance axis 51 of the second polarizing plate 50 is orthogonal to a transmittance axis 21 of the first polarizing plate 20. The transmittance measured as such satisfies the following Equation 1:

10%≤(B/A)×100≤50% [Equation 1]

wherein A is a transmittance in a state of the second polarizing plate being removed, and B is a transmittance measured after the second polarizing plate is placed on the polyimide-based film so that the transmittance axis of the second polarizing plate is orthogonal to the transmittance axis of the OLED polarizing plate.

The transmittance is measured using a spectrometer, and measurement is performed in a visible light region of 380 to 700 nm and then a value at 550 nm is set as a representative value.

FIG. 3 illustrates a method of measuring a transmittance of the multilayer structure as in FIG. 1, but the present invention is not limited thereto.

In Equation 1, it is confirmed that polarization is achieved well in a range of the transmittance of 10 to 50%, and the range may be specifically 15 to 45%, more specifically 20 to 40%.

The in-plane retardation and the in-plane slow axis (optic axis) of the polyimide-based film may be adjusted by the properties of the materials forming the polyimide-based film and a method of producing a film, which will be described in more detail below. The polyimide-based film described below is for illustrating one exemplary embodiment for satisfying the in-plane retardation and the in-plane slow axis (optic axis), and may be achieved by adjusting materials forming the film or adjusting the method of producing a film, and thus, is not limited thereto.

<Polyimide-Based Film>

In an exemplary embodiment of the present invention, the polyimide-based film may have an in-plane retardation of 300 nm or less, specifically 100 to 300 nm, as measured at a wavelength of 550 nm.

The in-plane retardation is a parameter defined as a product (ΔNxy×d) of anisotropy of refractive indexes of two orthogonal axes on a film (ΔNxy=|Nx−Ny|) and a film thickness d (nm), which is a measure showing optical isotropy and anisotropy. The in-plane retardation (R₀) is an in-plane retardation value at a wavelength of 550 nm and is represented by the following Mathematical Formula 4:

R₀=(nx−ny)×d [Mathematical Formula 4]

wherein nx is a refractive index in one-axis (x-axis) direction in a film plane, ny is a refractive index in one-axis direction orthogonal to the x-axis in the film plane, and d is a film thickness (nm).

In an exemplary embodiment of the present invention, the polyimide-based film may have a thickness of 10 to 500 μm, 20 to 250 μm, or 30 to 110 μm.

In addition, the polyimide-based film may have a modulus in accordance with ASTM D882 of 3 GPa or more, 4 GPa or more, 5 GPa or more, 6 GPa or more, or 7 GPa or more, an elongation at break of 8% or more, 12% or more, or 15% or more, a light transmittance of 5% or more or 5 to 80% as measured at 388 nm in accordance with ASTM D1746, a total light transmittance of 87% or more, 88% or more, or 89% or more as measured at 400 to 700 nm, a haze in accordance with ASTM D1003 of 2.0% or less, 1.5% or less, or 1.0% or less, a yellow index in accordance with ASTM E313 of 5.0 or less, 3.0 or less, or 0.4 to 3.0, and a b* value of 2.0 or less, 1.3 or less, or 0.4 to 1.3. In the range, the film has better physical properties to replace conventional glass as a window film.

In an exemplary embodiment of the present invention, the polyimide-based film is formed of a polyimide-based resin, and in particular, is a polyimide-based film having a polyamide-imide structure.

Preferably, the polyimide-based film may be a polyamide-imide-based resin including a fluorine atom and a aliphatic cyclic structure.

In an exemplary embodiment of the present invention, the polyamide-imide-based resin including a fluorine atom and an aliphatic cyclic structure may include a unit derived from a fluorine-based aromatic diamine, a unit derived from an aromatic dianhydride, and a unit derived from an aromatic diacid dichloride.

More preferably, in an exemplary embodiment of the present invention, as the polyamide-imide-based resin including a fluorine atom and an aliphatic cyclic structure, it is preferred to use a quaternary copolymer including a unit derived from a fluorine-based aromatic diamine, a unit derived from an aromatic dianhydride, a unit derived from a cycloaliphatic dianhydride, and a unit derived from an aromatic diacid dichloride, since it is more appropriate for expressing the physical properties to be desired.

In an exemplary embodiment of the present invention, as an example of the polyamide-imide-based resin including a fluorine atom and an aliphatic cyclic structure, a polyamide-imide polymer is preferred, which is prepared by preparing an amine-terminated polyamide oligomer derived from a first fluorine-based aromatic diamine and an aromatic diacid dianhydride and polymerizing the amine-terminated polyamide oligomer with monomers derived from a second fluorine-based aromatic diamine, an aromatic dianhydride, and a cycloaliphatic dianhydride, since the object of the present invention is achieved better.

The first fluorine-based aromatic diamine and the second fluorine-based aromatic diamine may be the same or different kinds. More specifically, an exemplary embodiment of the polyimide-based resin may include a block consisting of an amine-terminated polyamide oligomer derived from a first fluorine-based aromatic diamine and an aromatic diacid dichloride and a polyimide unit at both ends, and a content of the block may be 50% or more, based on the mass.

In an exemplary embodiment of the present invention, when the amine-terminated polyamide oligomer having an amide structure in a polymer chain formed by the aromatic diacid dichloride is included as the monomer of the diamine, not only optical physical properties but also in particular, mechanical strength including the modulus may be further improved and also the dynamic bending properties may be further improved, and thus, it may be appropriately used in a flexible OLED cover window.

In an exemplary embodiment of the present invention, when the polyamide oligomer block is included, a mole ratio between a diamine monomer including the amine-terminated polyamide oligomer and the second fluorine-based aromatic diamine and a dianhydride monomer including the aromatic dianhydride and the cycloaliphatic dianhydride of the present invention may be 1:0.9 to 1.1, specifically 1:1.

In addition, a content of the amine-terminated polyamide oligomer with respect to the entire diamine monomer is not particularly limited, but it is preferred to include the amine-terminated polyamide oligomer at 30 mol % or more, specifically 50 mol % or more, and more specifically 70 mol % or more for satisfying the mechanical physical properties, the yellow index, and the optical properties of the present invention.

In addition, a composition ratio of the aromatic dianhydride and the cycloaliphatic dianhydride is not particularly limited, but a ratio of 30 to 80 mol %:70 to 20 mol % is preferred considering achievement of the transparency, the yellow index, the mechanical physical properties, and the like of the present invention, but the present invention is not necessarily limited thereto.

In addition, the present invention may be a polyamide-imide-based resin including a fluorine atom and an aliphatic cyclic structure, which is a polyamide-imide-based resin obtained by mixing, polymerizing, and imidizing the fluorine-based aromatic diamine, the aromatic dianhydride, the cycloaliphatic dianhydride, and the aromatic diacid dichloride.

The resin has a random copolymer structure, may include 40 mol or more, specifically 50 to 80 mol of the aromatic diacid dichloride, 10 to 50 mol of the aromatic dianhydride, and 10 to 60 mol of the cyclic aliphatic dianhydride with respect to 100 mol of the diamine, and may be prepared by performing polymerization at a mole ratio of the sum of the diacid dichloride and the dianhydride to the diamine monomer of 1:0.9 to 1.1, specifically 1:1, but the present invention is not necessarily limited thereto.

The random polyamide-imide of the present invention is somewhat different in the optical properties such as transparency, the mechanical physical properties, and the retardation range as compared with the block polyamide-imide resin, but may belong to the scope of the present invention.

In an exemplary embodiment of the present invention, as the fluorine-based aromatic diamine component, a mixture of 2,2′-bis(trifluoromethyl)-benzidine and another known aromatic diamine component may be used, or 2,2′-bis(trifluoromethyl)-benzidine may be used alone. By using the fluorine-based aromatic diamine as such, excellent optical properties may be further improved and the yellow index may be further improved, based on the mechanical physical properties required in the present invention, as the polyamide-imide-based film. In addition, the tensile modulus of the polyamide-imide-based film may be improved to further improve the mechanical strength and to further improve the dynamic bending property of the hard coating film.

As the aromatic dianhydride, at least one or two or more of 4,4′-hexafluoroisopropylidene diphthalic anhydride (6FDA) and biphenyltetracarboxylic dianhydride (BPDA), oxydiphthalic dianhydride (ODPA), sulfonyl diphthalic anhydride (SO2DPA), (isopropylidenediphenoxy) bis(phthalic anhydride) (6HDBA), 4-(2,5-dioxotetrahydrofuran-3-yl)-1,2,3,4-tetrahydronaphthalene-1,2-dicarboxylic dianhydride (TDA), 1,2,4,5-benzene tetracarboxylic dianhydride (PMDA), benzophenone tetracarboxylic dianhydride (BTDA), bis(carboxylphenyl) dimethyl silane dianhydride (SiDA), and bis(dicarboxyphenoxy) diphenyl sulfide dianhydride (BDSDA) may be used, but the present invention is not limited thereto.

As an example of the cycloaliphatic dianhydride, any one or a mixture of two or more selected from the group consisting of 1,2,3,4-cyclobutanetetracarboxylic dianhydride (CBDA), 5-(2,5-dioxotetrahydrofuryl)-3-methylcyclohexene-1,2-dicarboxylic dianhydride (DOCDA), bicyclo[2.2.2]oct-7-en-2,3,5,6-tetracarboxylic dianhydride (BTA), bicyclooxtene-2,3,5,6-tetracarboxylic dianhydride (BODA), 1,2,3,4-cyclopentanetetracarboxylic dianhydride (CPDA), 1,2,4,5-cyclohexanetetracarboxylic dianhydride (CHDA), 1,2,4-tricarboxy-3-methylcarboxycyclopentane dianhydride (TMDA), 1,2,3,4-tetracarboxycyclopentane dianhydride (TCDA), and derivatives thereof may be used.

In an exemplary embodiment of the present invention, when the amide structure in the polymer chain is formed by the aromatic diacid dichloride, not only the optical physical properties but also the mechanical strength particularly including the modulus may be further greatly improved, and also the dynamic bending properties may be further improved, which is thus preferred.

As the aromatic diacid dichloride, any one or a mixture of two or more selected from the group consisting of isophthaloyl dichloride (IPC), terephthaloyl dichloride (TPC), [1,1′-biphenyl]-4,4′-dicarbonyl dichloride (BPC), 1,4-naphthalene dicarboxylic dichloride (NPC), 2,6-naphthalene dicarboxylic dichloride (NTC), 1,5-naphthalene dicarboxylic dichloride (NEC), and derivatives thereof may be used, but the present invention is not limited thereto.

A weight average molecular weight of the polyimide resin in the present invention is not particularly limited, but may be 200,000 g/mol or more, preferably 300,000 g/mol or more, and more preferably 200,000 to 500,000 g/mol. In addition, a glass transition temperature is not limited, but may be 300 to 400° C., more specifically 330 to 380° C. Within the range, since a film with a high modulus, an excellent mechanical strength, and excellent optical physical properties, and being less curled may be provided, which is more preferred, but the present invention is not necessarily limited thereto.

<Method of Producing Polyimide-Based Film>

Hereinafter, a method of producing a polyimide-based film having the properties of the present invention will be illustrated.

In an exemplary embodiment of the present invention, the polyimide-based film may be produced by applying an “polyimide-based resin solution” including a polyimide-based resin and a solvent on a substrate, and then performing drying or drying/stretching. That is, the substrate layer may be prepared by a solution casting method.

As an example, the method may include the following: an amine-terminated oligomer preparation step of reacting a fluorine-based aromatic diamine and an aromatic diacid dichloride to prepare an oligomer; a step of reacting the thus-prepared oligomer with the fluorine-based aromatic diamine, an aromatic dianhydride, and a cycloaliphatic dianhydride to prepare a polyamic acid solution; a step of imidizing the polyamic acid solution to prepare a polyamide-imide resin; and a step of applying a polyamide-imide solution in which the polyamide-imide resin is dissolved in an organic solvent to form a film.

Hereinafter, each step will be described in more detail, taking a case of producing a block polyamide-imide film as an example.

The step of preparing an oligomer may include reacting the fluorine-based aromatic diamine and the aromatic diacid dichloride and purifying and drying the obtained oligomer. In this case, the fluorine-based aromatic diamine may be introduced at a mole ratio of 1.01 to 2 with respect to the aromatic diacid dichloride to prepare an amine-terminated polyamide oligomer monomer. A molecular weight of the oligomer monomer is not particularly limited, but for example, when the weight average molecular weight is in a range of 1000 to 3000 g/mol, better physical properties may be obtained.

In addition, it is preferred to use an aromatic carbonyl halide monomer such as terephthaloyl chloride or isophthaloyl chloride, not terephthalic ester or terephthalic acid itself for introducing an amide structure, and this is, though is not clear, considered to have an influence on the physical properties of the film by a chlorine element.

Next, the step of preparing a polyamic acid may be carried out by a solution polymerization reaction in which the thus-prepared amine-terminated fluorine-based substituted polyamide oligomer is reacted with the fluorine-based aromatic diamine, the aromatic dianhydride, and the cycloaliphatic dianhydride in an organic solvent. Here, the organic solvent used for the polymerization reaction may be, as an example, any one or two or more polar solvents selected from dimethylacetamide (DMAc), N-methyl-2-pyrrolidone (NMP), dimethylformamide (DMF), dimethylformsulfoxide (DMSO), ethyl cellosolve, methyl cellosolve, acetone, diethyl acetate, m-cresol, and the like.

Next, the step of carrying out imidization to prepare a polyamide-imide resin may be carried out by chemical imidization, and more preferably, a polyamic acid solution is chemically imidized using pyridine and an acetic anhydride. Subsequently, imidization may be carried out using an imidization catalyst and a dehydrating agent at a low temperature of 150° C. or lower, preferably 100° C. or lower, and more specifically 50 to 150° C.

By the method as such, uniform mechanical physical properties may be imparted to the entire film as compared with the case of an imidization reaction by heat at a high temperature.

As the imidization catalyst, any one or or two or more selected from pyridine, isoquinoline, and β-quinoline may be used. In addition, as the dehydrating agent, any one or two or more selected from an acetic anhydride, a phthalic anhydride, a maleic anhydride, and the like may be used, but the present invention is not necessarily limited thereto.

In addition, an additive such as a flame retardant, an adhesion improver, inorganic particles, an antioxidant, a UV inhibitor, and a plasticizer may be mixed with the polyamic acid solution to prepare the polyamide-imide resin.

In addition, after the imidization, the resin is purified using a solvent to obtain a solid content, which may be dissolved in a solvent to obtain a polyamide-imide solution. The solvent may include, for example, N,N-dimethyl acetamide (DMAc) and the like, but is not limited thereto.

The step of forming a film from the polyamide-imide solution is carried out by applying the polyamide-imide solution on a substrate, and then drying the solution in a drying step divided into a dry area. In addition, stretching may be carried out before or after the drying, and a heat treatment step may be further carried out after the drying or stretching step. As the substrate, for example, glass, stainless steel, a film, or the like may be used, but the present invention is not limited thereto. Application may be carried out by a die coater, an air knife, a reverse roll, a spray, a blade, casting, gravure, spin coating, and the like.

More preferably, for imparting retardation to the produced film, a stretching process may be included after drying the film. Stretching conditions are not limited as long as the physical properties of an in-plane retardation of 300 nm or less as measured at a wavelength of 550 nm are satisfied.

In an exemplary embodiment, the stretching process may be performed by a stretching area divided into three or more areas, and a stretching ratio may be adjusted while the temperature is gradually raised in each stretching area. Here, a stretching ratio may be gradually increased, and shrinkage stretching may be performed at the end area. Specifically, for example, when stretching is performed in three stretching areas, in a first stretching area and a second stretching area, the stretching ratio may be increased with a gradual rise in temperature, and in a third stretching area, shrinkage stretching with a decreased stretching ratio as compared with the previous step, the second stretching area, may be carried out. Here, the temperature may be equivalent to or higher than the second stretching area, but is not limited thereto.

<Flexible OLED Device>

Another embodiment of the present invention provides a flexible OLED display device including: an OLED display panel and the flexible OLED cover window described above formed on the display panel.

Specifically, the flexible OLED display device includes an OLED panel; and a flexible OLED cover window on an upper surface of the OLED panel, wherein the flexible OLED cover window includes a polarizing plate; and one layer or more of a polyimide-based film on the polarizing plate.

In addition, an adhesive layer formed between the polarizing plate and the OLED panel may be included.

Hereinafter, the present invention will be described in more detail with reference to the Examples and Comparative Examples. However, the following Examples and Comparative Examples are only an example for describing the present invention in more detail, and do not limit the present invention in any way.

1) Modulus/Elongation at Break

The Modulus/elongation at break was measured by measured using UTM 3365 available from Instron, under the condition of pulling a polyamide-imide film having a thickness of 50 μm, a length of 50 mm, and a width of 10 mm at 25° C. at 50 mm/min, in accordance with ASTM D882. The unit of the modulus was GPa and the unit of the elongation at break was %.

2) Light Transmittance

In accordance with the standard of ASTM D1746, a total light transmittance was measured at the entire wavelength area of 400 to 700 nm using a spectrophotometer (from Nippon Denshoku, COH-400) and a single wavelength light transmittance was measured at 388 nm using UV/Vis (Shimadzu, UV3600), on a film having a thickness of 50 μm. The unit was %.

3) Haze

In accordance with the standard of ASTM D1003, the haze was measured using a spectrophotometer (from Nippon Denshoku, COH-400), on a film having a thickness of 50 μm. The unit was %.

4) Yellow Index (YI) and b* Value

The yellow index and the b* value were measured using a colorimeter (from HunterLab, ColorQuest XE), on a film having a thickness of 50 μm, in accordance with the standard of ASTM E313.

5) Weight Average Molecular Weight (Mw) and Polydispersity Index (PDI)

The weight average molecular weight and the polydispersity index of the produced films were measured as follows.

First, a film sample was dissolved in a DMAc eluent containing 0.05 M LiBr and used as a sample.

Measurement was performed by using GPC (Waters GPC system, Waters 1515 isocratic HPLC Pump, Waters 2414 Reflective Index detector), connecting Olexis, polypore, and mixed D columns as a GPC column, using a DMAc solution as a solvent, and using polymethylmethacrylate (PMMA STD) as a standard, and analysis was performed at a flow rate of 1 mL/min at 35° C.

6) Pencil Hardness

For the films produced in the Examples and the Comparative Examples, according to JIS K5400, a line of 20 mm was drawn at a rate of 50 mm/sec on the film using a load of 750 g, this operation was repeated 5 times or more, and the pencil hardness was measured based on the case in which scratches occurred once or less.

7) Measurement of Residual Solvent Content

For a residual solvent content, a value obtained by subtracting a weight at 370° C. from a weight at 150° C. using TGA (Discovery from TA) was determined as a residual solvent content in the film. Here, measurement conditions were heating up to 400° C. at a heating rate of 10° C./min and a weight change in a region from 150 to 370° C. was measured.

8) Retardation Measurement

A retardation property was measured using Axoscan (OPMF, Axometrics Inc.). A sample having an appropriate size was placed on a stage and an in-plane retardation (R₀) at a wavelength of 550 nm was measured. A light source of a 1 mm beam size was used, and the retardation was measured while the sample was moved at intervals of 1 mm in length and width for an area of 100×100 mm².

9) Visibility

A visibility level is determined depending on the presence of optical mura. Mura, color uniformity, and the like which occur when a film sample having a larger area than 100×100 mm was looked at various angles through a three-wavelength lamp were confirmed, and it was determined that the visibility was good when a color was uniform and a contour form was less shown when observed with the naked eye.

Good: no rainbow mura seen, uniform color shown

Normal: little rainbow mura seen, uniform color shown

Poor: strong rainbow mura seen, strong color shown

10) Polarized Light Transmittance

A second polarizing plate having a polarization degree of 99% was placed on the produced flexible OLED cover window, to be orthogonal to the transmittance axis of the OLED polarizing plate, and a transmittance was measured in this state. A polarized light transmittance may be measured as shown in the following Equation 1:

10%≤(B/A)×100≤50% [Equation 1]

wherein A is a transmittance in a state of the second polarizing plate being removed, and B is a transmittance measured after the second polarizing plate is placed on the polyimide film so that the transmittance axis of the second polarizing plate is orthogonal to the transmittance axis of the OLED polarizing plate.

The transmittance is measured using a spectrometer, and measurement is performed in a visible light region of 380 to 700 nm and then a value at 550 nm is set as a representative value.

11) Reflectance

A reflectance was measured using a chromatic color-difference meter (CM-5, Konica-minolta) or UV-vis (UV3600, SHIMADZU) equipment. A sample having a certain size was placed on a stage, and the reflectance was measured at a visible light wavelength (380-700 nm). A value at a wavelength of 550 nm was set as a representative value.

### Preparation Example 1

<Production of Polyimide-Based Film>

Terephthaloyl chloride (TPC) and 2,2′-bis(trifluoromethyl)-benzidine (TFMB) were added to a mixed solution of dichloromethane and pyridine in a reactor, and stirring was performed at 25° C. for 2 hours under a nitrogen atmosphere. Here, a mole ratio of TPC:TFMB was 300:400, and a solid content was adjusted to 10 wt %. Thereafter, the reactant was precipitated in an excessive amount of methanol and filtered to obtain a solid content, which was dried under vacuum at 50° C. for 6 hours or more to obtain an oligomer, and the prepared oligomer had a formula weight (FW) of 1650 g/mol.

N,N-dimethylacetamide (DMAc), 100 mol of the oligomer, and 28.6 mol of 2,2′-bis(trifluoromethyl)-benzidine (TFMB) were added to the reactor and sufficient stirring was performed. After confirming that the solid raw material was completely dissolved, fumed silica (surface area of 95 m₂/g, <1 μm) was added to DMAc at a content of 1000 ppm relative to the solid content, and added to the reactor after being dispersed using ultrasonic waves. 64.3 mol of cyclobutanetetracarboxylic dianhydride (CBDA) and 64.3 mol of 4,4′-hexafluoroisopropylidene diphthalic anhydride (6FDA) were subsequently added, sufficient stirring was performed, and the mixture was polymerized at 40° C. for 10 hours. Here, the solid content was 12%. Subsequently, each of pyridine and acetic anhydride was added sequentially at 2.5-fold relative to the total content of dianhydride, and stirring was performed at 60° C. for 12 hours.

After the polymerization was completed, the polymerization solution was precipitated in an excessive amount of methanol and filtered to obtain a solid content, which was dried under vacuum at 50° C. for 6 hours or more to obtain polyamide-imide powder. The powder was diluted and dissolved at 20 wt % in DMAc to prepare a polyimide-based resin solution.

The thus-prepared polyimide-based resin solution was applied on a PET film using roll-to-roll coating equipment, and then dried at 100° C. for 3 minutes and at 200° C. for 3 minutes. Subsequently, the thus-dried polyimide-based film was separated from the PET film, and the substrate film was stretched using a pin tenter. A stretching area was divided into three stretching areas; 1.01-fold stretching at 160° C. in a first stretching area, 1.02-fold stretching at 200° C. in a second stretching area, and 1.01-fold stretching at 230° C. in a third stretching area were performed.

The residual solvent content of the film which had passed through the stretching area was 1.3 wt %. The thus-produced polyamide-imide film had a thickness of 50 μm, a transmittance at 388 nm of 70%, a total light transmittance of 89.9%, a haze of 0.4, a yellow index (YI) of 1.7, a b* value of 1.0, a modulus of 6.5 GPa, an elongation at break of 21.2%, a weight average molecular weight of 310,000 g/mol, a polydispersity index (PDI) of 2.21, a pencil hardness of H/750 g, and an in-plane retardation of 400 nm or less.

### Example 1

A polyamide-imide film produced above having an in-plane retardation of 400 nm was placed on a polarizing plate for OLED available from Sumitomo Chemical Co., Ltd. so that an angle between the transmittance axis of the polarizing plate and the in-plane slow axis (optic axis) of the polyamide-imide film was 5°, thereby producing a flexible OLED cover window.

The thus-produced flexible OLED cover window was assembled in an OLED panel, and the physical properties thereof were evaluated and are shown in Table 1.

### Example 2

A flexible OLED cover window was produced in the same manner as in Example 1, except that the polyamide-imide film was placed so that an angle between the transmittance axis of the polarizing plate and the in-plane slow axis (optic axis) of the polyamide-imide film was 10°.

The thus-produced flexible OLED cover window was assembled in an OLED panel, and the physical properties thereof were evaluated and are shown in Table 1.

### Example 3

A flexible OLED cover window was produced in the same manner as in Example 1, except that the polyamide-imide film was placed so that an angle between the transmittance axis of the polarizing plate and the in-plane slow axis (optic axis) of the polyamide-imide film was 15°.

The thus-produced flexible OLED cover window was assembled in an OLED panel, and the physical properties thereof were evaluated and are shown in Table 1.

### Example 4

A flexible OLED cover window was produced in the same manner as in Example 1, except that the polyamide-imide film was placed so that an angle between the transmittance axis of the polarizing plate and the in-plane slow axis (optic axis) of the polyamide-imide film was 20°.

The thus-produced flexible OLED cover window was assembled in an OLED panel, and the physical properties thereof were evaluated and are shown in Table 1.

### Example 5

In Example 1, two layers of the produced polyamide-imide films were placed on the polarizing plate using an optical adhesive (8146 series available from 3M) Here, a first polyamide-imide film was placed so that an angle between the in-plane slow axis (optic axis) of the first polyamide-imide film in contact with the polarizing plate and the transmittance axis of the polarizing plate was 5° and a second polyamide-imide film was placed on the first polyamide-imide film so that an angle between the in-plane slow axes (optic axes) of the first polyamide-imide film and the second polyamide-imide film was 5°, thereby producing a flexible OLED cover window.

The thus-produced flexible OLED cover window was assembled in an OLED panel, and the physical properties thereof were evaluated and are shown in Table 1.

### Comparative Example 1

A flexible OLED cover window was produced in the same manner as in Example 1, except that the polyamide-imide film was placed so that an angle between the transmittance axis of the polarizing plate and the in-plane slow axis (optic axis) of the polyamide-imide film was 25°.

The thus-produced flexible OLED cover window was assembled in an OLED panel, and the physical properties thereof were evaluated and are shown in Table 1.

### Comparative Example 2

A flexible OLED cover window was produced in the same manner as in Example 1, except that a polyamide-imide film having an in-plane retardation of 350 mm was used, as shown in Table 1.

The thus-produced flexible OLED cover window was assembled in an OLED panel, and the physical properties thereof were evaluated and are shown in Table 1.

TABLE 1

| | Example | Example | Example | Example | Example | Comparative | Comparative |
|---|---|---|---|---|---|---|---|
| | 1 | 2 | 3 | 4 | 5 | Example 1 | Example 2 |
| In-plane | 43 | 52 | 60 | 71 | 82 | 150 | 350 |
| retardation (nm) | | | | | | | |
| Angle 1) | 5 | 10 | 15 | 20 | 5 | 25 | 45 |
| Angle 2) | — | — | — | — | 5 | — | — |
| Polarizing plate | 250 | 250 | 250 | 250 | 250 | 250 | 250 |
| thickness (μm) | | | | | | | |
| Visibility | Good | Good | Good | Good | Good | Normal | Poor |
| Transmittance (%) | 88.7 | 88.3 | 88.3 | 88.9 | 88.4 | 82.1 | 79.4 |
| Reflectance (%) | 11.3 | 11.7 | 11.7 | 11.1 | 11.6 | 17.9 | 20.6 |

In Table 1, angle 1) is an angle between the in-plane slow axis (optic axis) of the polyimide-based film in first contact with the OLED polarizing plate and the transmittance axis or the absorption axis of the OLED polarizing plate, and angle 2) is an angle between the in-plane slow axes (optic axes) of two sheets of the polyimide-based films.

The flexible cover window according to the present invention may be thinned, may be flexible to provide an OLED display which may be bent, rolled, and the like, and may minimize color mixing to provide a better visibility effect.

In addition, the flexible cover window may be applied to all kinds of free form-factor display devices such as a rollable or foldable device.

Hereinabove, although the present invention has been described by specific matters, limited exemplary embodiments, and drawings, they have been provided only for assisting the entire understanding of the present invention, and the present invention is not limited to the exemplary embodiments, and various modifications and changes may be made by those skilled in the art to which the present invention pertains from the description.

Therefore, the spirit of the present invention should not be limited to the above-described exemplary embodiments, and the following claims as well as all modified equally or equivalently to the claims are intended to fall within the scope and spirit of the invention.

What is claimed is:

1. A flexible cover window on a display, the flexible cover window comprising: a polarizing plate on an organic light emitting diode and a polyimide film layer on the polarizing plate,
wherein the polyimide film layer has one or two or more layers of polyimide-based films having an in-plane retardation of 300 nm or less as measured at a wavelength of 550 nm, and an angle between an in-plane slow axis (optic axis) of the polyimide-based film which is adjacent to the polarizing plate and a transmittance axis or an absorption axis of the polarizing plate is 20° or less.

2. The flexible cover window of claim 1, wherein when two or more layers of the polyimide-based films are placed on the polarizing plate, an angle between in-plane slow axis (optic axis) of adjacent polyimide-based films is 20° or less.

3. The flexible cover window of claim 1, wherein the polyimide-based film has the in-plane retardation of 100 to 300 nm as measured at a wavelength of 550 nm.

4. The flexible cover window of claim 1, wherein a transmittance satisfies the following Equation 1, as measured in a state in which a second polarizing plate having a polarization degree of 99% or more is placed on the polyimide film layer to be orthogonal to the transmittance axis of the polarizing plate:
10%≤(B/A)×100≤50% [Equation 1]
wherein A is a transmittance in a state of the second polarizing plate being removed, and B is a transmittance measured after the second polarizing plate is placed on the polyimide-based film so that the transmittance axis of the second polarizing plate is orthogonal to the transmittance axis of the polarizing plate.

5. The flexible cover window of claim 1, wherein the polyimide-based film has a modulus in accordance with ASTM D882 of 3 GPa or more, an elongation at break of 8% or more, a light transmittance of 5% or more as measured at 388 nm in accordance with ASTM D1746, a total light transmittance of 87% or more as measured at 400 to 700 nm, a haze of 2.0% or less, a yellow index of 5.0 or less, and a b* value of 2.0 or less as measured by a colorimeter.

6. The flexible cover window of claim 1, wherein the polyimide-based film is formed of a polyamide-imide-based resin.

7. The flexible cover window of claim 6, wherein the polyimide-based film includes a unit derived from a fluorine-based aromatic diamine, a unit derived from an aromatic dianhydride, and a unit derived from an aromatic diacid dichloride.

8. The flexible cover window of claim 7, wherein the polyimide-based film further includes a unit derived from a cycloaliphatic dianhydride.

9. The flexible cover window of claim 1, wherein the polyimide-based film has a thickness of 30 to 110 μm.

10. The flexible cover window of claim 1, wherein an adhesive layer is included on one surface or both surfaces of the polyimide-based film.

11. The flexible cover window of claim 1, wherein a hard coating layer is included on one surface or both surfaces of the polyimide-based film.

12. The flexible cover window of claim 1, wherein the polarizing plate includes a polarizer and a λ/4 retardation layer.

13. A flexible display device comprising the flexible cover window of claim 1.

14. The flexible display device of claim 13, wherein the display device is an organic light emitting diode display device.
